(19) United States
(12) Patent Application Publication
(10) Pub. No.: US 2010/0006864 A1
(43) Pub. Date: Jan. 14, 2010

(54) IMPLANTED CONNECTORS IN LED SUBMOUNT FOR PEC ETCHING BIAS

(75) Inventor: Daniel A. Steigerwald, Cupertino, CA (US)

Correspondence Address: PATENT LAW GROUP LLP, 2635 NORTH FIRST STREET, SUITE 223, SAN JOSE, CA, 95134, US

(73) Assignees: Philips Lumileds Lighting Company, LLC, San Jose, CA (US); Koninklijke Philips Electronics N.V., Eindhoven (NL)

(21) Appl. No.: 12/172,182

(22) Filed: Jul. 11, 2008

(51) Int. Cl. H01L 33/00

(52) U.S. Cl. 257/88; 257/99; 438/28; 257/E33.056

(57) ABSTRACT

A sapphire growth substrate wafer has epitaxially grown over it N-type layers, an active layer, and P-type layers to form GaN LEDs. Each LED is a flip-chip with its cathode contact and anode contact formed on the same side. The wafer is then diced to separate out the LEDs. A P-type silicon submount wafer has N-type doped interconnect regions for interconnecting all the cathode contacts together after the LEDs are mounted on the submount wafer. The sapphire substrate is then removed by a laser lift-off process. A bias voltage is then applied to the cathode contacts via the interconnect regions to bias the N-type layers for a photo-electrochemical etching process that roughens the exposed layer for increased light extraction. The submount wafer is then diced, cutting through the doped interconnect regions.

### FIELD OF THE INVENTION

This invention relates to forming light emitting diodes (LEDs) and, in particular, to a method for electrically biasing an exposed LED layer during photo-electrochemical etching.

### BACKGROUND

Flip-chip LEDs have reflective p and n contacts on a bottom surface of the LED, and the contacts are directly connected to bonding pads on a submount. Light generated by the LED is primarily emitted through the top surface of the LED surface. In this way, the contacts do not block the light, and wire bonds are not needed.

The efficiency of flip-chip gallium-nitride (GaN) LEDs can be increased by removing the transparent sapphire growth substrate after all the LED layers have been epitaxially grown. After the removal of the substrate, the exposed GaN layer is etched to thin the layer and to create a roughened surface to increase light extraction. A good etching technique for the exposed layer is photo-electrochemical (PEC) etching, which involves electrically biasing the layer to be etched, immersing the LED in a base solution containing a biased electrode, and applying UV light to the exposed layer. Exposure to the UV light generates electron-hole pairs in the semiconductor layer. The holes migrate to the surface of the GaN layer under the influence of the electric field, then react with the GaN and base solution at the surface to break the GaN bonds. The exposed layer is typically an N-type confining layer or a semi-insulating layer (e.g., a lattice matching layer) over the N-type layer.

One method that has been used by the Applicant for biasing the exposed LED layer is to provide a grounded metal pattern on the submount wafer for temporarily interconnecting the N-layers of the LEDs mounted on the wafer so the exposed layer is electrically biased during the PEC etching. After the PEC etching, when the submount wafer is sawed to dice the LEDs, the biasing metal is cut so has no effect on the subsequent operation of each singulated LED.

Applicant has found that one problem with using the metal pattern on the submount for biasing is that, when sawing the submount wafer for dicing, the metal can be smeared along the sidewall of the submount die and form a leakage path through the submount or to another lead. Removing the smeared metal adds time and cost to the fabrication.

What is needed is an efficient technique to bias the exposed layer of LEDs mounted on a submount wafer during PEC etching that does not have the drawbacks of the metal pattern described above.

### SUMMARY

A wafer-scale process is described that simultaneously etches, using PEC etching, any number of LEDs mounted on a single submount wafer. Flip-chip LEDs are formed over a sapphire substrate. The LEDs are singulated and mounted on a silicon submount wafer. The sapphire substrate is then removed from each LED die using a laser lift-off process. The exposed layer of the LED then needs to be etched for thinning and roughening to increase light extraction. A PEC etching process is used, where all the LEDs mounted on the submount are etched simultaneously. Instead of a metal pattern for biasing all the N-type layers of the LEDs during PEC etching, conductive doped regions are formed in the silicon surface that interconnect the N-type layers of all the LEDs mounted on the silicon submount. The doped regions are connected to a bias source such as ground. The interconnections are formed across areas of the submount wafer that will later be sawed for singulation so that, after singulation, the doped interconnect regions have no effect on the operation of the individual LEDs.

In one embodiment, doped regions are formed in the silicon submount wafer that contact the anode and cathode of each LED on the wafer for acting as a zener diode for electrostatic discharge (ESD) protection. The doped interconnect regions for temporary biasing the N-layers during PEC etching can be formed at the same time that the zener diodes are formed so that there is no extra resources required for forming the interconnect regions.

Therefore, the problems with the metal pattern used for biasing are avoided.

Aspects of the process may be applied to LEDs that are not GaN, such as AlInGaP LEDs.

### BRIEF DESCRIPTION OF THE DRAWINGS

FIG. 1 is a simplified cross-sectional view of a conventional flip-chip LED that may be used in conjunction with the invention.

FIG. 2 is a simplified top down view of a portion of a silicon submount wafer showing N+ doped zener diode regions, anode and cathode metal pads over the diode regions, and N+ doped interconnect regions for interconnecting and biasing the cathodes of all the LEDs later mounted on the wafer.

FIG. 3 is a cross-sectional view along line 3-3 of FIG. 2 illustrating the LED dies mounted on the submount wafer of FIG. 2 undergoing a sapphire substrate laser lift-off process.

FIG. 4 illustrates the PEC etching of the exposed LED layer while the layer is biased using the doped interconnect regions.

FIG. 5 is a flowchart showing various steps used in one embodiment of the invention.

Elements identified by the same numeral in the various figures are the same or similar.

### DETAILED DESCRIPTION

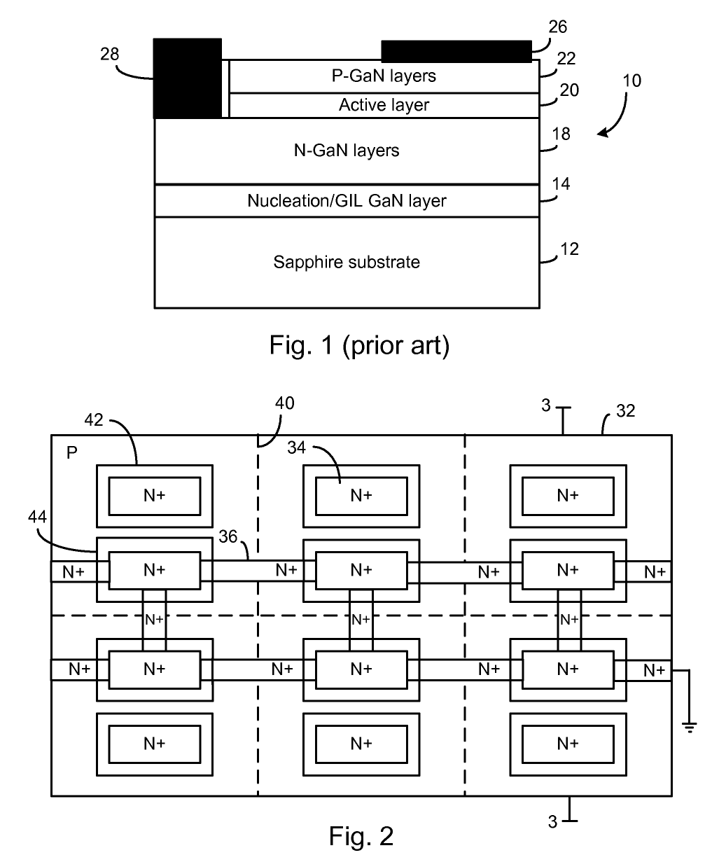

FIG. 1 is a simplified cross-sectional view of an LED 10 that may be conventional. In the example, the LED 10 is a GaN LED; however, other types of LEDs may be used instead, such as AlInGaP LEDs formed over a GaAs or GaP growth substrate. All the layers are epitaxially grown.

On a sapphire substrate 12 is grown a conventional GaN nucleation layer, a growth initiation layer (GIL), and a coalescence layer, all represented by the layer 14. Such layers are generally used to provide a transition between the sapphire substrate 12 lattice constant and the LED layers' GaN lattice constant to minimize the defect density in the crystalline structure of the critical N—GaN, active, and P—GaN layers. Forming such transition layers are described in U.S. Pat. Nos. 6,989,555 and 6,630,692, assigned to the present assignee and incorporated by reference.

Over layer 14 is grown various conventional N—GaN confining layers 18, a conventional active layer 20, and conventional P—GaN confining layers 22. In one embodiment, the active layer 20 is AlInGaN and generates blue light.

Since the LEDs are to be flip-chips, with the N and P contacts on the surface of the LEDs facing the submount, the top P-layer 22 is masked and etched to expose portions of the underlying N-layer 18. Then, metal ohmic contacts 26 and 28 to the P and N semiconductor layers are formed. There will normally be hundreds or thousands of flip-chip LEDs 10 simultaneously created on the same growth substrate.

The LEDs are then singulated by sawing, or scribing and breaking, or using another technique to form individual LED dies.

FIG. 2 is a top down view of a small portion of a silicon submount wafer 32 on which the LEDs 10 will later be mounted. For simplicity, the LEDs are assumed to be rectangular and will be mounted in an X-Y grid on the submount wafer. Many other anode and cathode metal contact patterns may be used to create a more uniform current along the active layer, such as a polka dot pattern, an interdigitated fingers pattern, or other pattern.

The silicon submount wafer 32 is grown to have a P-type conductivity, such a being doped with boron. Therefore, the silicon is intrinsically P-type. For protecting the LEDs from ESD, zener diodes are formed in the wafer 32 connected to the anode and cathode contacts. The zener diodes are designed to break down at a voltage above the operating voltage of the LEDs but below the voltage that would damage the LEDs. The zener diodes are formed by implanting or diffusing an N-type dopant, such as phosphorus, arsenic, or antimony, into regions 34 of the P-type wafer 32 to form N+ regions. Conventional masking and implantation techniques may be used for the doping. The density and depth of the dopants, as well as the doping level of the silicon substrate, primarily determine the zener breakdown voltage. In the final LED product, the P-type submount body is typically grounded during operation to shunt excess voltage to ground when a zener diode conducts.

At the same time as the zener diodes are being formed, the mask also exposes regions 36 that connect between the regions 34 for adjacent LED cathodes. These interconnect regions 36 are doped exactly like the zener diode regions 34, so add no extra fabrication steps are needed. Many types of patterns of the regions 34 and 36 may be used, depending on the layout of the LEDs and the metallization pattern on the LEDs. Upon later singulation of the wafer 32 along lines 40, the cathode interconnections provided by regions 36 will be cut.

After the doped regions are formed, a metal layer is then deposited on the wafer 32 and patterned to form anode and cathode bonding pads 42 and 44 for each LED. The pads 42 and 44 overlie and are in electrical contact with the zener diode regions 34. The locations of the pads 42 and 44 correspond to the P and N contacts 26 and 28 (FIG. 1) on the LEDs 10.

The cathode bonding pads 44 and the interconnect regions 36 are shown schematically connected to ground, but the connection is temporarily made during a later PEC etching process by connecting any cathode metal lead on the wafer 32 to ground.

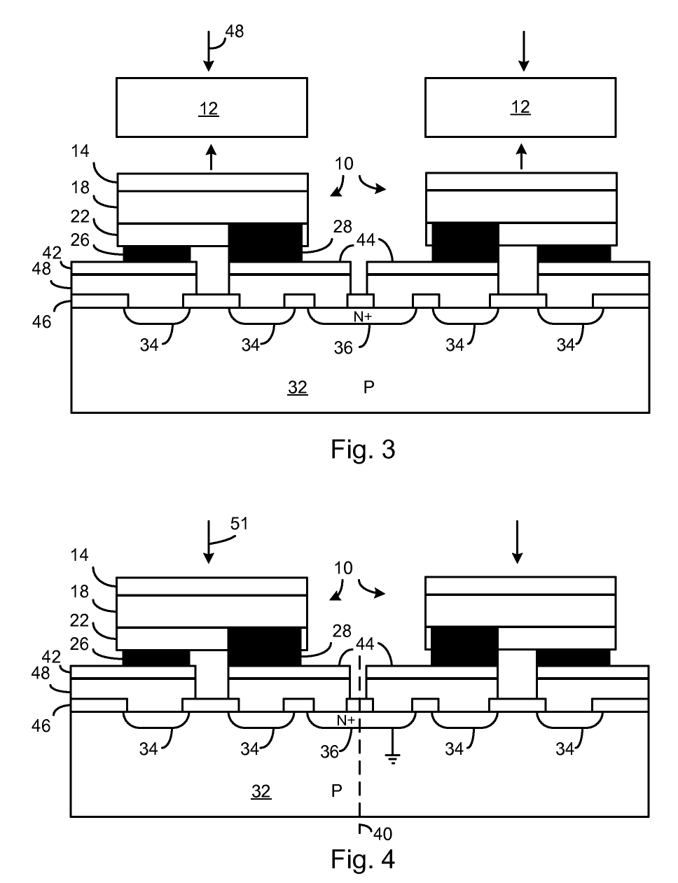

As shown in FIG. 3, the singulated LEDs 10 are mounted on the silicon submount wafer 32 by ultrasonic welding, soldering, or other conventional technique. Gold balls may act as an interface metal. FIG. 3 is a cross-sectional view across the line 3-3 of FIG. 2, which cuts across the anode and cathode metal contacts of two LEDs 10 as well as their cathode interconnect region 36. For simplicity in FIG. 3, the active layer 20 is not shown.

Prior to the LEDs 10 being mounted on the wafer 32, an insulating layer 46, such as SiO₂, is grown or deposited over the surface of the silicon wafer 32 and etched to expose the doped regions 34 and 36. A metal layer 48, such as an aluminum alloy, is then deposited over the surface to contact the doped regions 34 and 36. The metal layer 48 may include multiple layers typically used to electrically contact a doped silicon region. A metal bonding layer, such as gold, is then deposited and etched, along with the metal layer 48, to form the anode and cathode bonding pads 42 and 44 for ultrasonic bonding to the LED metal contacts 26 and 28.

The metal layer 48 also forms anode and cathode leads that extend out beyond each LED's periphery and terminate in pads (not shown) for connection to a power supply, such as by connecting to a leadframe in a package.

An insulating underfill material, such as silicone, is injected under each LED die to protect the die from contamination and provide mechanical support for the die during a substrate laser lift-off process.

As shown in FIG. 3, the sapphire substrate 12 is removed by laser lift-off. The laser energy is shown by arrows 48. The photon energy of the laser (e.g., an excimer laser) is selected to be above the band gap of the LED material and below the absorption edge of the sapphire substrate (e.g., between 3.44 eV and 6 eV). Pulses from the laser through the sapphire are converted to thermal energy within the first 100 nm of the LED material. The generated temperature is in excess of 1000° C. and dissociates the gallium and nitrogen. The resulting high gas pressure pushes the substrate 12 away from the epitaxial layers to release the substrate from the layers, and the loose substrate is then simply removed from the LED structure.

The mechanical support provided by the underfill and metal contacts prevents the tremendous downward pressure from cracking the LEDs 10.

The growth substrate 12 may instead be removed by etching, such as reactive ion etching (RIE), CMP, or grinding. Suitable substrate removal techniques are described in U.S. Pat. No. 7,256,483, entitled, Package-Integrated Thin Film LED, by John Epler et al., incorporated herein by reference.

After the growth substrate 12 is removed, the LED is thinned and the surface of the exposed layer (14 or 18) is roughened to achieve optimal light extraction through the surface. For such thinning and roughening, photo-electrochemical (PEC) etching is used. Removal of the layer 14 prior to PEC is optional since the electrical field created between the N-type layers 18 and the base solution (described below) would still exist with the layer 14 inbetween. The layer 14 may be removed by PEC etching or non-PEC etching, such as by RIE, CMP, or grinding, to reveal the N-type layers 18.

In PEC etching, an electric field should be created between the surface to be etched and the solution to increase the rate of etching and control the etch rate. To enable such biasing, the cathodes of the LEDs 10 are coupled to ground via the doped interconnect regions 36. Even connecting one of the LED's cathode metal leads to ground connects all the cathodes on the wafer 32 to ground via the interconnect regions 36.

As shown in FIG. 4, the PEC etch 51 of the exposed surface of layer 14 or 18 is performed. Layer 14 may be completely etched through during the PEC etch. To perform the PEC etching, at least the layer to be etched is immersed in a base solution, and an electrode with a positive potential is immersed in the base solution. An example of a suitable base solution is 0.2 M KOH, though many other suitable basic or acidic solutions may be used and depend on the composition of the material to be etched and the desired surface texture. The epitaxial surface of the GaN layer 14/18 is exposed to light with energy greater than the band gap of the surface layer. In one example, ultraviolet light with a wavelength of about 365 nm and an intensity between about 10 and about 100 mW/cm² is used. Exposure to the light generates electron-hole pairs in the semiconductor layer. The holes migrate to the surface of the GaN layer under the influence of the electric field. The holes then react with the GaN and the base solution at the surface to break the GaN bonds, according to the equation 2GaN+6OH⁻+6e⁺=2Ga(OH)₃+N₂. The current through the N-type layers 18 via the interconnect regions 36 may be about 10 uA for each 1×1 mm² LED. The PEC voltage should be kept below the diode breakdown voltage (e.g., below 5 volts). Additional detail of PEC etching of a GaN layer may be found in U.S. publication 20060014310, by John Epler, assigned to the present assignee and incorporated herein by reference.

The resulting roughening of the surface of layer 18 reduces the internal reflections within the LED structure to increase efficiency.

After the PEC etch, the submount wafer 32 is sawed or broken along the dashed line 40 to singulate the LEDs. Singulating the LEDs cuts through the interconnect regions 36 so they have no further effect.

Prior to singulation, wafer level phosphor deposition and encapsulation may additionally be performed by molding, deposition, or other technique. If the LEDs emit blue light, the phosphor layer can contain green and red phosphors so that the combination of the leaked blue light with the green and red light creates white light. A yellow-green YAG phosphor may be used instead. A lens may be formed over each LED by a wafer-level molding process.

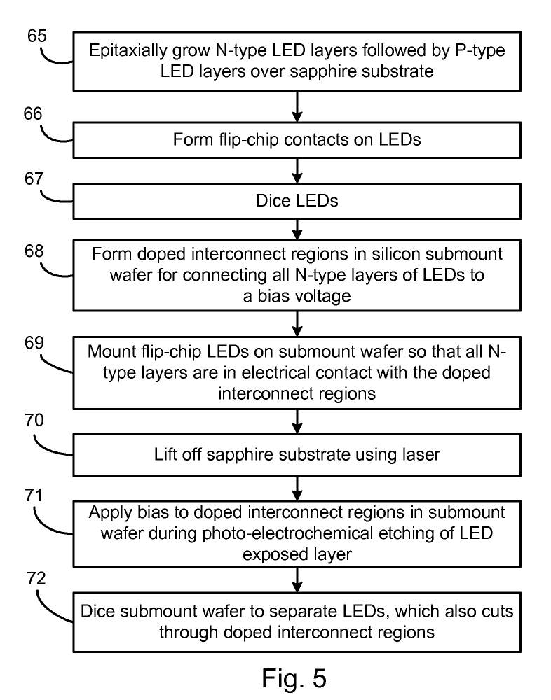

FIG. 5 is a flowchart identifying various steps used in one embodiment of the invention. The order of the steps is not critical to the invention.

In step 65, N-type LED layers, followed by P-type LED layers are epitaxially grown over a sapphire substrate. Other types of growth substrates may also be used.

In step 66, the LEDs are processed to form the flip-chip metal contacts.

In step 67, the LEDs are diced.

In step 68, a silicon submount wafer is processed by forming doped interconnect regions for electrically interconnecting all the cathodes (N-type layers) of the LEDs to a bias voltage during a PEC etch.

In step 69, the individual flip-chip LEDs are mounted on the submount wafer so that all the N-type layers can be later electrically biased due to their electrical contact with the grounded interconnect regions. Other bias voltages can be used.

In step 70, the sapphire substrate is removed, such as by laser lift-off.

In step 71, a bias voltage (e.g., ground) is applied to the N-type layers via the interconnect regions during a PEC etch of the exposed layer. A single cathode lead on the submount wafer may be used for applying the bias voltage to the cathodes of all the LEDs mounted on the wafer.

In step 72, the submount wafer is diced to separate the LEDs, which also cuts through the interconnect regions.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

1. A method for fabricating a light emitting diode (LED) structure comprising:
providing a plurality of flip-chip LEDs, each LED comprising at least one N-type layer epitaxially grown over a growth substrate, an active layer epitaxially grown over the at least one N-type layer, at least one P-type layer epitaxially grown over the active layer, a cathode metal contact on a first side of the LED electrically connected to the at least one N-type layer, and an anode metal contact on the first side of the LED electrically connected to the at least one P-type layer;
providing a semiconductor submount wafer having a first conductivity type first surface;
doping portions of the first conductivity type first surface with dopants of an opposite second conductivity type to form first interconnect regions on the first surface of the submount wafer;
mounting the plurality of flip-chip LEDs on the first surface of the submount wafer so that each cathode metal contact is in electrical contact with one or more of the first interconnect regions, wherein the first interconnect regions connect all of the cathode metal contacts together;
removing the growth substrate from each of the LEDs to expose an epitaxially grown layer;
electrically biasing the cathode metal contact of each LED with a bias voltage via the first interconnect regions so that the at least one N-type layer of each LED is electrically biased;
performing a photo-electrochemical etch of the exposed epitaxial layer while biasing the at least one N-type layer of each LED; and
dicing the submount wafer to cut across the first interconnect regions.

2. The method of claim 1 wherein the exposed epitaxial layer comprises a lattice matching layer grown prior to the at least one N-type layer.

3. The method of claim 1 wherein performing the photo-electrochemical etch comprises immersing the submount wafer in a base solution, applying UV light to the exposed epitaxial layer, and biasing the base solution to create an electric field between the base solution and the at least one N-type layer.

4. The method of claim 1 wherein electrically biasing the cathode metal contact of each LED comprises grounding the cathode metal contact of each LED via the first interconnect regions.

5. The method of claim 1 wherein doping portions of the first conductivity type first surface with dopants of an opposite second conductivity type comprises doping portions of a P-type conductivity first surface of the submount wafer with N-type dopants.

6. The method of claim 5 wherein the submount wafer is an intrinsic P-type silicon wafer.

7. The method of claim 1 wherein the growth substrate comprises a sapphire substrate, and removing the growth substrate comprises applying laser light through the sapphire substrate to lift off the sapphire substrate from over the epitaxially grown layers.

8. The method of claim 1 further comprising forming second conductivity type regions in the first conductivity type first surface of the submount wafer, the second conductivity type regions forming zener diodes connected to each cathode metal contact and each anode metal contact to provide electrostatic discharge (ESD) protection, wherein the first interconnect regions are formed at the same time as forming the second conductivity type regions.

9. The method of claim 1 wherein performing a photo-electrochemical etch comprises etching the exposed layer to roughen a surface of the exposed epitaxial layer to improve light extraction from each LED.

10. An intermediate light emitting diode (LED) structure during a fabrication process, the LED structure comprising:
a plurality of flip-chip LEDs, each LED comprising at least one N-type layer epitaxially grown over a growth substrate, an active layer epitaxially grown over the at least one N-type layer, at least one P-type layer epitaxially grown over the active layer, a cathode metal contact on a first side of the LED electrically connected to the at least one N-type layer, and an anode metal contact on the first side of the LED electrically connected to the at least one P-type layer;
a semiconductor submount wafer having a first conductivity type first surface and doped regions of an opposite second conductivity type forming first interconnect regions on the first surface of the submount wafer;
the plurality of flip-chip LEDs being mounted on the first surface of the submount wafer so that each cathode metal contact is in electrical contact with one or more of the first interconnect regions, wherein the first interconnect regions connect all of the cathode metal contacts together;
the growth substrate being removed from each of the LEDs to expose an epitaxially grown layer; and
the cathode metal contact of each LED being biased with a bias voltage via the first interconnect regions so that the at least one N-type layer of each LED is electrically biased during a photo-electrochemical etch of the exposed epitaxial layer.

11. A light emitting diode (LED) structure comprising:
a flip-chip LED comprising at least one N-type layer epitaxially grown over a growth substrate, an active layer epitaxially grown over the at least one N-type layer, at least one P-type layer epitaxially grown over the active layer, a cathode metal contact on a first side of the LED electrically connected to the at least one N-type layer, and an anode metal contact on the first side of the LED electrically connected to the at least one P-type layer;
a semiconductor submount having a first conductivity type first surface with doped regions of an opposite second conductivity type forming first interconnect regions on the first surface of the submount; and
the flip-chip LED being mounted on the first surface of the submount wafer so that the cathode metal contact is in electrical contact with one or more of the first interconnect regions, wherein the one or more first interconnect regions terminate at an edge of the submount where the submount has been cut away from other portions of a submount wafer.

12. The structure of claim 11 further comprising second conductivity type regions in the first conductivity type first surface of the submount, the second conductivity type regions forming zener diodes connected to the cathode metal contact and the anode metal contact to provide electrostatic discharge (ESD) protection, wherein the one or more first interconnect regions, prior to the submount being cut away from other portions of a submount wafer, electrically connect between second conductivity regions providing zener diodes for cathode metal contacts on other LEDs mounted on the submount wafer.

13. The structure of claim 11 wherein the submount is intrinsic P-type silicon and the one or more first interconnect regions are N-type.
